(19) United States
(12) Patent Application Publication
(10) Pub. No.: US 2023/0292505 A1
(43) Pub. Date: Sep. 14, 2023

(54) SEMICONDUCTOR DEVICE AND METHOD FOR MANUFACTURING SEMICONDUCTOR DEVICE

(71) Applicant: KIOXIA CORPORATION, Tokyo (JP)

(72) Inventors: Shinichi FURUKAWA, Yokohama Kanagawa (JP); Saori Kashiwada, Yokkaichi Mie (JP); Takashi Ichikawa, Saitama Saitama (JP)

(21) Appl. No.: 17/897,056

(22) Filed: Aug. 26, 2022

(30) Foreign Application Priority Data
Mar. 8, 2022 (JP) 2022-035368

(51) Int. Cl. H01L 27/11582; H01L 27/11519; H01L 27/11556; H01L 27/11565

(52) U.S. Cl. CPC H01L 27/11582; H01L 27/11519; H01L 27/11556; H01L 27/11565

(57) ABSTRACT

According to one embodiment, a semiconductor device includes a substrate, a first film including electrode layers and insulating layers alternately stacked on the substrate, and a plurality of insulating films in the first film. The insulating films extend in a first direction parallel to a surface of the substrate and spaced from one another in a second direction parallel to the surface of the substrate. The semiconductor device further includes a semiconductor layer provided in at least one of the insulating films and first and second charge accumulation units between the semiconductor layer and one of the electrode layers. The insulating films include a first insulating film having a first width in the second direction and a second insulating film having a second width in the second direction that is greater than the first width.

### CROSS-REFERENCE TO RELATED APPLICATION(S)

This application is based upon and claims the benefit of priority from Japanese Patent Application No. 2022-035368, filed Mar. 8, 2022, the entire contents of which are incorporated herein by reference.

### FIELD

Embodiments described herein relate generally to a semiconductor device and a method of manufacturing a semiconductor device.

### BACKGROUND

When an insulating film embedded in a trench is annealed during a manufacturing process, a crack may be generated in the insulating film.

### BRIEF DESCRIPTION OF THE DRAWINGS

FIG. 1 is a vertical cross-sectional view illustrating a semiconductor device according to a first embodiment.

FIGS. 2A and 2B are transverse cross-sectional views of a semiconductor device according to a first embodiment.

FIG. 3 is another transverse cross-sectional view of a semiconductor device according to a first embodiment.

FIGS. 4A, 4B, and 4C are transverse cross-sectional views depicting aspects related to a method for manufacturing a semiconductor device according to a first embodiment.

FIGS. 5A, 5B, and 5C are transverse cross-sectional views (depicting aspects related to a method for manufacturing a semiconductor device according to a first embodiment.

FIG. 6 is a cross-sectional view illustrating aspects related to a method for manufacturing a semiconductor device according to a comparative example.

FIG. 7 is a cross-sectional view illustrating aspects related to a method for manufacturing a semiconductor device according to a first embodiment.

FIGS. 8A and 8B are cross-sectional views illustrating aspects of a method for manufacturing a semiconductor device according to a first embodiment.

FIGS. 9A and 9B are cross-sectional views illustrating aspects of a method for manufacturing a semiconductor device according to a first embodiment.

FIGS. 10A and 10B are cross-sectional views illustrating aspects of a method for manufacturing a semiconductor device according to a first embodiment.

FIGS. 11A and 11B are cross-sectional views illustrating aspects of a method for manufacturing a semiconductor device according to a first embodiment.

FIGS. 12A and 12B are cross-sectional views illustrating aspects of a method for manufacturing a semiconductor device according to certain modifications of a first embodiment.

FIGS. 13A and 13B are cross-sectional views illustrating aspects of a method for manufacturing a semiconductor device according to another modification of a first embodiment.

FIG. 14 is a transverse cross-sectional view schematically illustrating a structure of a semiconductor device according to a first embodiment.

FIG. 15 is a transverse cross-sectional view schematically illustrating a structure of a semiconductor device according to a modification of the first embodiment.

FIG. 16 is a plan view illustrating a semiconductor device according to a second embodiment.

FIG. 17 is another plan view illustrating a semiconductor device according to a second embodiment.

FIG. 18 is yet another plan view illustrating a semiconductor device according to a second embodiment.

FIG. 19 is an enlarged plan view illustrating aspects of a semiconductor device according to a second embodiment.

FIG. 20 is a cross-sectional view of a semiconductor device according to a second embodiment.

FIG. 21 is a transverse cross-sectional view schematically illustrating aspects of a semiconductor device according to the second embodiment.

FIG. 22 is a transverse cross-sectional view schematically illustrating aspects of a semiconductor device according to a modification of a second embodiment.

### DETAILED DESCRIPTION

Embodiments provide a semiconductor device having reduced generation of cracks in an insulating film and a method for manufacturing the same.

In general, according to one embodiment, a semiconductor device includes a substrate and a first film on the substrate. The first film includes a plurality of electrode layers and a plurality of insulating layers alternately stacked. A plurality of insulating films are in the first film, these insulating films extend in a first direction parallel to a surface of the substrate and are spaced from each other in a second direction parallel to the surface of the substrate but intersecting the first direction. A semiconductor layer is disposed in at least one of the plurality of insulating films. A first charge accumulation unit is between a first one of the electrode layers and the semiconductor layer in the second direction. A second charge accumulation unit is between a second one of the electrode layers and the semiconductor layer in the second direction. The semiconductor layer is between the first and second charge accumulation units in the second direction. The plurality of insulating films include a first insulating film having a first width in the second direction and a second insulating film having a second width in the second direction. The second width is greater than the first width.

Hereinafter, certain example embodiments of the present disclosure will be described with reference to the drawings. In the drawings, the same or substantially the same components are denoted by the same reference signs, and redundant description will be omitted.

### First Embodiment

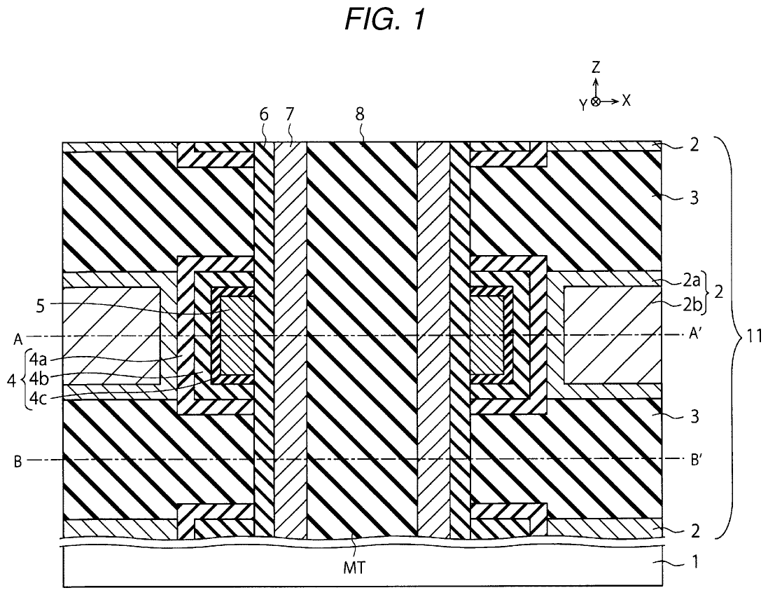

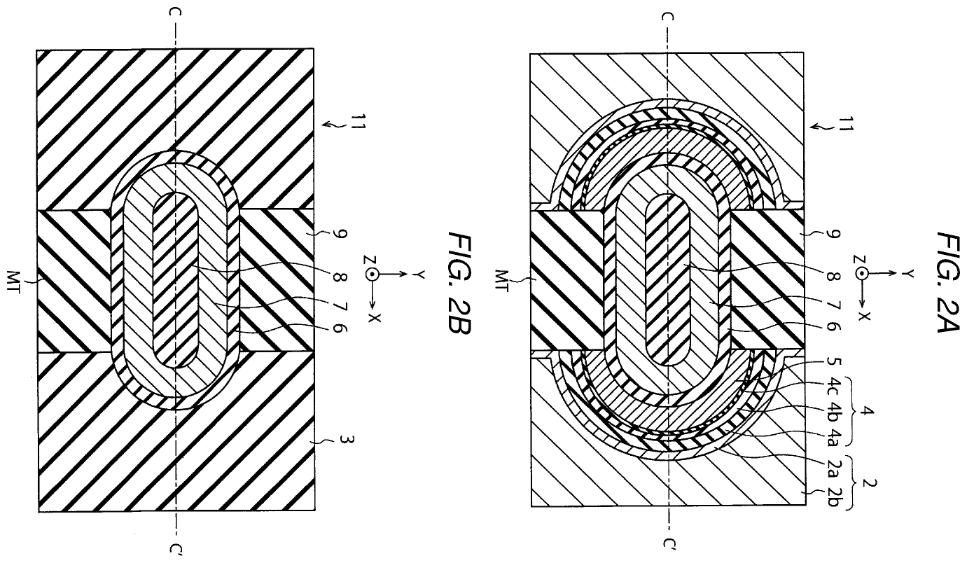

FIG. 1 is a vertical cross-sectional view illustrating a structure of a semiconductor device according to a first embodiment, and FIGS. 2A and 2B are transverse cross-sectional views illustrating a structure of a semiconductor device according to a first embodiment. FIGS. 2A and 2B illustrate transverse cross sections taken along a line A-A′ and a line B-B′ of FIG. 1. FIG. 1 illustrates a vertical cross section taken along a line C-C′ of FIGS. 2A and 2B. The semiconductor device according to the present embodiment is, for example, a three-dimensional memory device.

As illustrated in FIGS. 1, 2A, and 2B, the semiconductor device according to the first embodiment includes a substrate 1, a plurality of control gates 2, a plurality of insulating layers 3, a plurality of block insulating films 4, a plurality of floating gates 5, a tunnel insulating film 6, a channel semiconductor layer 7, a core insulating film 8, and an embedded insulating film 9. The control gate 2 is an example of an electrode layer. The floating gate 5 is an example of a charge accumulation unit. The channel semiconductor layer 7 is an example of a semiconductor layer.

Each control gate 2 includes a barrier metal layer 2a and an electrode material layer 2b. Each block insulating film 4 includes an insulating film 4a, an insulating film 4b, and an insulating film 4c. FIGS. 1, 2A, and 2B further illustrate a multilayer film 11 alternately including the control gates 2 and the insulating layers 3. The multilayer film 11 is an example of a first film.

The substrate 1 illustrated in FIG. 1 is, for example, a semiconductor substrate such as a silicon substrate. FIGS. 1, 2A, and 2B illustrate an X direction and a Y direction parallel to a surface of the substrate 1 and perpendicular to each other, and a Z direction perpendicular to the surface of the substrate 1. The X direction, the Y direction, and the Z direction intersect with each other. In the description, a +Z direction is treated as an upward direction, and a −Z direction is treated as a downward direction. The −Z direction may or may not coincide with a gravitational direction. The Y direction is an example of a first direction, and the X direction is an example of a second direction.

The plurality of control gates 2 and the plurality of insulating layers 3 illustrated in FIG. 1 are alternately stacked on the substrate 1 to form the multilayer film 11. FIG. 2A illustrates a cross section at a control gate 2, and FIG. 2B illustrates a cross section at an insulating layer 3.

Each control gate 2 in this example includes the barrier metal layer 2a and the electrode material layer 2b. The barrier metal layer 2a is formed on an upper surface of a lower insulating layer 3, a lower surface of an upper insulating layer 3, and side surfaces of the block insulating film 4 and the embedded insulating film 9. The electrode material layer 2b is formed on an upper surface, a lower surface, and a side surface of the barrier metal layer 2a. The barrier metal layer 2a is, for example, a titanium nitride film (TiN film). The electrode material layer 2b is, for example, a tungsten (W) layer. Each control gate 2 functions as a word line of a three-dimensional memory device or the like.

Each insulating layer 3 in this example is formed on upper surfaces of a lower control gate 2 and the block insulating film 4, lower surfaces of an upper control gate 2 and the block insulating film 4, and side surfaces of the tunnel insulating film 6 and the embedded insulating film 9. Each insulating layer 3 is, for example, a silicon oxide film (SiO₂ film).

The semiconductor device according to the first embodiment further includes a memory trench MT formed in the multilayer film 11. The memory trench MT extends along the Z direction and the Y direction and penetrates the multilayer film 11. The embedded insulating film 9 illustrated in FIGS. 2A and 2B is embedded in the memory trench MT and extends along the Z direction and the Y direction. At least a part of each of the core insulating film 8, the channel semiconductor layer 7, and the tunnel insulating film 6 is formed in the embedded insulating film 9 (see FIGS. 2A and 2B). In FIG. 2A, a pair of floating gates 5 are formed in the multilayer film 11 so as to sandwich the core insulating film 8, the channel semiconductor layer 7, and the tunnel insulating film 6 therebetween along the X direction. Similarly, a pair of block insulating films 4 are formed in the multilayer film 11 so as to sandwich the core insulating film 8, the channel semiconductor layer 7, and the tunnel insulating film 6.

Each block insulating film 4 in this example includes an insulating film 4a, an insulating film 4b, and an insulating film 4c. The insulating films 4a, 4b, and 4c are sequentially formed on the upper surface of the lower insulating layer 3, the lower surface of the upper insulating layer 3, and a side surface of the control gate 2. Each of the insulating films 4a, 4b, and 4c is, for example, a SiO₂ film or a metal oxide film.

As illustrated in FIGS. 1 and 2A, each floating gate 5 is formed on the upper surface of the lower insulating layer 3, the lower surface of the upper insulating layer 3, and the side surface of the control gate 2 via the block insulating film 4. Each floating gate 5 is, for example, a polysilicon layer or a metal layer. Each floating gate 5 can accumulate signal charges of the three-dimensional memory for storing data or the like. The pair of floating gates 5 illustrated in FIG. 2A is an example of first and second charge accumulation units. The semiconductor device according to the first embodiment may include a silicon nitride film (SiN film) as a charge accumulation unit instead of the floating gate 5.

The tunnel insulating film 6, the channel semiconductor layer 7, and the core insulating film 8 are sequentially formed on side surfaces of the insulating layer 3, the block insulating film 4, the floating gate 5, and the embedded insulating film 9. The tunnel insulating film 6 has a tubular shape extending lengthwise (axially) in the Z direction. Similarly, the channel semiconductor layer 7 has a tubular shape extending lengthwise (axially) in the Z direction. The core insulating film 8 has a columnar shape extending lengthwise (axially) in the Z direction. The tunnel insulating film 6 is, for example, a SiO₂ film or a silicon oxynitride film (SiON film). The channel semiconductor layer 7 is, for example, a polysilicon layer. The core insulating film 8 is, for example, a SiO₂ film.

As illustrated in FIGS. 2A and 2B, the embedded insulating film 9 is embedded in the multilayer film 11 and extends in both the Z direction and the Y direction. The embedded insulating film 9 is, for example, a SiO₂ film. The embedded insulating film 9 may also contain impurity elements (dopants).

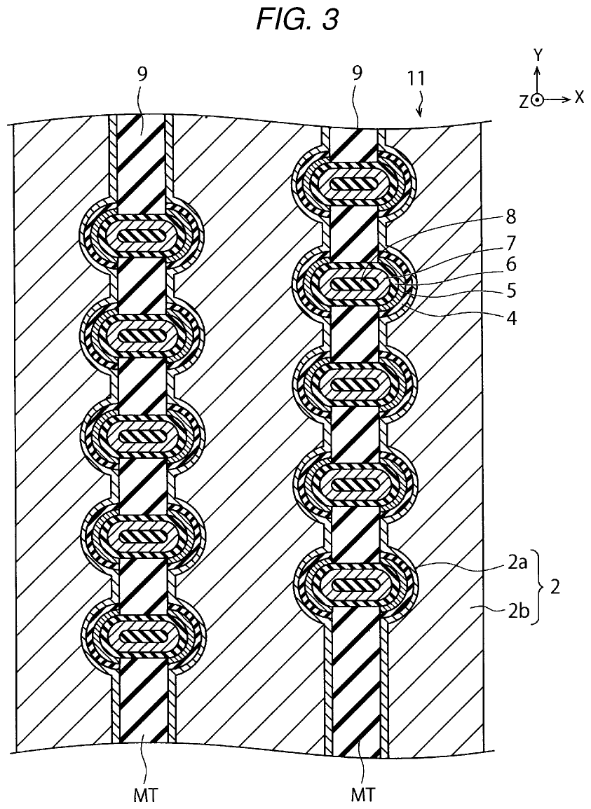

FIG. 3 is another transverse cross-sectional view illustrating the structure of the semiconductor device according to the first embodiment.

The semiconductor device according to the first embodiment includes a plurality of memory trenches MT formed in the multilayer film 11. These memory trenches MT each extend in the Z direction and the Y direction, and are arranged with respect to each other in the X direction. FIGS. 2A and 2B illustrate one of these memory trenches MT, and FIG. 3 illustrates two of these memory trenches MT. Similar to FIG. 2A, FIG. 3 illustrates cross sections of the control gates 2.

The semiconductor device according to the first embodiment further includes a plurality of embedded insulating films 9 embedded in the plurality of memory trenches MT. These embedded insulating films 9 extend in the Z direction and the Y direction, and are arranged with respect to each other in the X direction. FIG. 3 illustrates two of these embedded insulating films 9.

In FIG. 3, five different sets, each including a core insulating film 8, a channel semiconductor layer 7, and a tunnel insulating film 6, are formed in each of the embedded insulating films 9. Each set of the core insulating film 8, the channel semiconductor layer 7, and the tunnel insulating film 6 is sandwiched between a pair of floating gates 5 and a pair of block insulating films 4. Structures of the core insulating film 8, the channel semiconductor layer 7, the tunnel insulating film 6, the floating gate 5, and the block insulating film 4 for these sets are the same as those illustrated in FIGS. 1, 2A, and 2B. In FIG. 3, ten sets of a core insulating film 8, a channel semiconductor layer 7, and a tunnel insulating film 6 are arranged in a so-called staggered pattern.

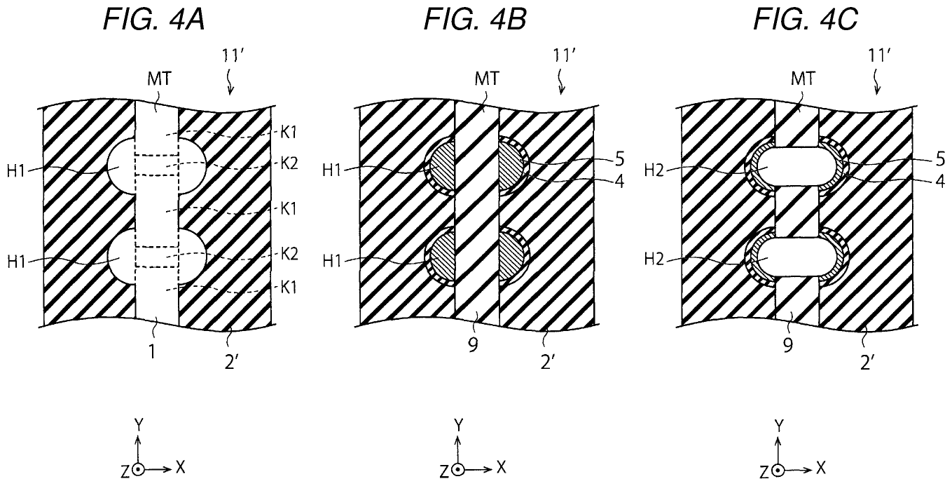

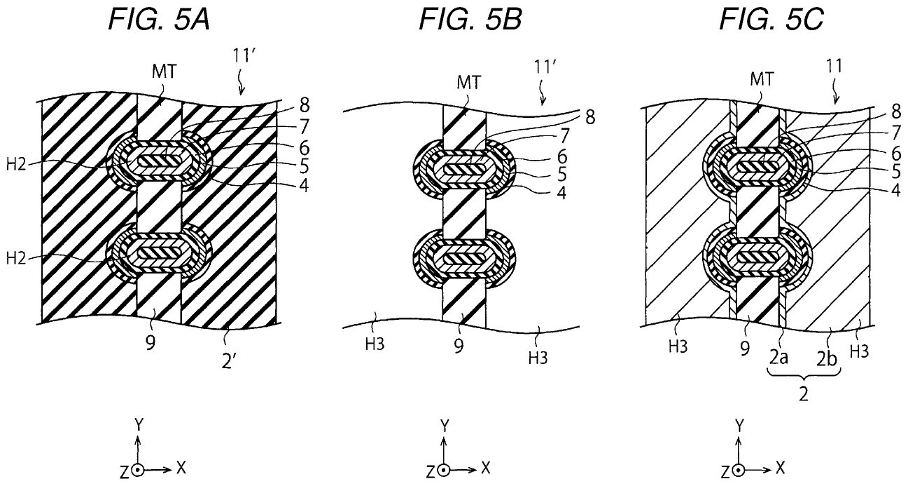

FIGS. 4A, 4B, and 4C and FIGS. 5A, 5B, and 5C are transverse cross-sectional views for illustrating a method for manufacturing the semiconductor device according to the first embodiment.

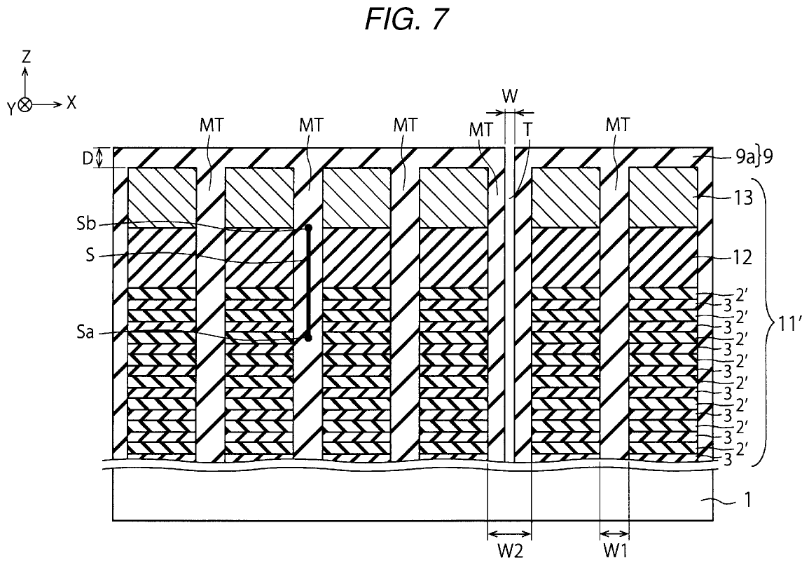

First, the substrate 1 is prepared, and a plurality of sacrificial layers 2′ and the plurality of insulating layers 3 are alternately stacked on the substrate 1 (FIG. 4A). These sacrificial layers 2′ and insulating layers 3 are stacked as illustrated in a part of FIG. 7. As a result, a multilayer film 11′ alternately including these sacrificial layers 2′ and insulating layers 3 is formed on the substrate 1. The sacrificial layer 2′ and the insulating layer 3 are examples of a first layer and a second layer, respectively. The multilayer film 11′ is an example of a first film. Each sacrificial layer 2′ is, for example, a SiN film. FIG. 4A illustrates a transverse cross section at one sacrificial layer 2′ included in the multilayer film 11′.

Next, the plurality of memory trenches MT are formed in the multilayer film 11′ by lithography and reactive ion etching (RIE) (FIG. 4A). These memory trenches MT extend in the Z direction and the Y direction and are spaced from each other in the X direction. The memory trenches MT are formed so as to penetrate the multilayer film 11′. FIG. 4A illustrates just one of these memory trenches MT though a plurality are similarly formed.

Next, a plurality of recesses H1 are formed at predetermined positions in the sacrificial layers 2′ by wet etching through these memory trenches MT (FIG. 4A). FIG. 4A illustrates two pairs of recesses H1 that sandwich the memory trench MT therebetween. A shape of each recess H1 is, for example, a shape close to a semicircle in a plan view (for example, a shape of a part of an oval or an ellipse). These recesses H1 are formed by, for example, forming a hard mask film (or resist film) in each memory trench MT, processing the hard mask film in each memory trench MT into a plurality of mask patterns arranged in the Y direction, and isotropically processing portions of the sacrificial layers 2′ not covered with these mask patterns by the wet etching. FIG. 4A illustrates the regions K1 in which the mask patterns are formed and the regions K2 in which the mask patterns are not formed. The region K2 serves as an opening through which a chemical liquid (an etchant) reaches to each sacrificial layer 2′. As illustrated in FIG. 4A, a width of each opening (region K2) in the Y direction is set to be narrower than a width of each recess H1 in the Y direction. In other words, as a result of isotropic wet etching, the width of each recess H1 in the Y direction becomes wider than the width of each opening (region K2) in the Y direction.

Next, the block insulating film 4 and the floating gate 5 are selectively embedded in each recess H1 by film formation and etching to form the embedded insulating film 9 in each memory trench MT (FIG. 4B). As a result, the block insulating film 4 and the floating gate 5 are sequentially formed on an upper surface, a lower surface, and a side surface of the recess H1. The block insulating film 4 is formed by sequentially forming the insulating films 4a, 4b, and 4c (see FIG. 1 and the like). FIG. 4B illustrates the embedded insulating film 9 being embedded in the entire memory trench MT.

Next, a plurality of recesses H2 are formed in the embedded insulating films 9 by lithography and RIE (FIG. 4C). Each recess H2 is formed spanning across a pair of floating gates 5 and the embedded insulating film 9. Each recess H2 according to the first embodiment is formed so as to penetrate these floating gates 5 and the embedded insulating film 9. A shape of each recess H2 is, for example, an oval or an ellipse in a plan view.

Next, the tunnel insulating film 6, the channel semiconductor layer 7, and the core insulating film 8 are sequentially formed in each recess H2 (FIG. 5A). As a result, the tunnel insulating film 6, the channel semiconductor layer 7, and the core insulating film 8 are disposed so as to be sandwiched between a pair of floating gates 5 and a pair of block insulating films 4.

Next, a slit is formed in the multilayer film 11′, and each sacrificial layer 2′ is removed by wet etching via the slit (FIG. 5B). As a result, a plurality of cavities H3 are formed in the multilayer film 11′ at the previous levels/positions of the sacrificial layers 2′.

Next, the barrier metal layer 2a and the electrode material layer 2b are formed in each cavity H3 (FIG. 5C). As a result, the control gate 2 is formed in each cavity H3, and the multilayer film 11 alternately including control gates 2 and insulating layers 3 is formed on the substrate 1. That is, the plurality of sacrificial layers 2′ are replaced with the plurality of control gates 2. In this way, the semiconductor device according to the first embodiment is manufactured.

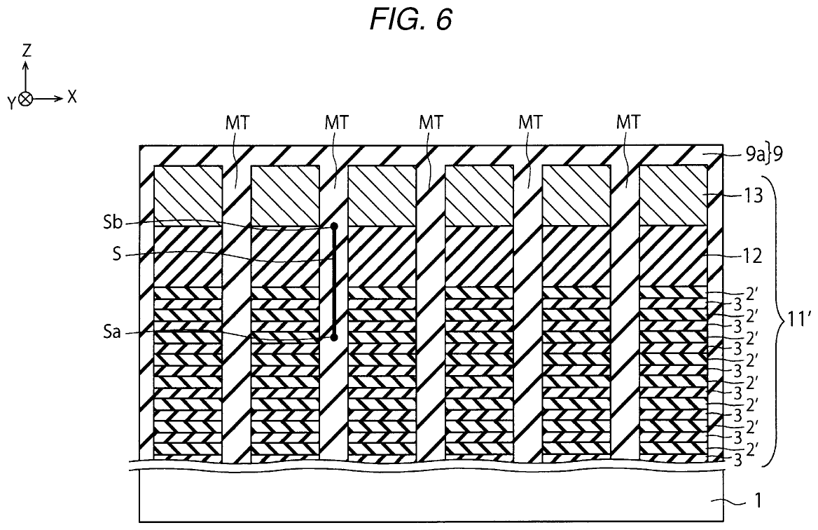

Next, aspects of the first embodiment and a comparative example will be compared with reference to FIGS. 6 and 7.

FIG. 6 is a vertical cross-sectional view illustrating a method for manufacturing a semiconductor device according to the comparative example.

FIG. 6 illustrates a step corresponding to the step illustrated in FIG. 5A. FIG. 6 illustrates the substrate 1 and the multilayer film 11′ formed on the substrate 1. The multilayer film 11′ includes the plurality of sacrificial layers 2′ and the plurality of insulating layers 3 alternately stacked on the substrate 1, a mask layer 12, and a mask layer 13. The mask layer 12 is, for example, a SiO₂ film. The mask layer 13 is, for example, a polysilicon layer.

FIG. 6 further illustrates a plurality of memory trenches MT formed in the multilayer film 11′ and the embedded insulating film 9 that has been formed in these memory trenches MT. The embedded insulating film 9 is divided into separate portions for each memory trench MT in a subsequent step, but is not yet divided in FIG. 6. The embedded insulating film 9 includes an insulating film 9a. The insulating film 9a is, for example, a SiO₂ film. The insulating film 9a is an example of a first insulating material.

FIG. 6 further illustrates a seam S that can be formed form in the insulating film 9a when the insulating film 9a is filled into the memory trenches MT. The seam S illustrated in FIG. 6 extends in the Z direction within just one memory trench MT. A reference sign Sa denotes a lower end of the seam S, and a reference sign Sb denotes an upper end of the seam S. When such an insulating film 9a is annealed, the seam S may cause a crack to form in the insulating film 9a. For example, when the insulating film 9a is annealed, stress may be generated in the insulating film 9a due to thermal shrinkage of the insulating film 9a, this stress may act on or at the seam S, and a crack may be generated starting from the seam S. As a result, the semiconductor device may become defective.

FIG. 7 is a vertical cross-sectional view illustrating the method for manufacturing the semiconductor device according to the first embodiment.

FIG. 7 also illustrates the step illustrated in FIG. 5A. FIG. 7 illustrates substantially the same components as those illustrated in FIG. 6. However, the memory trenches MT according to the first embodiment include a plurality of memory trenches MT having a width W1 in the X direction, and a plurality of memory trenches MT having a width W2 in the X direction. FIG. 7 illustrates four memory trenches MT having the width W1 and one memory trench MT having the width W2 among these memory trenches MT. The width W2 is set to be wider than the width W1 (W2>W1). The width W1 is an example of a first width, and the memory trench MT having the width W1 is an example of a first trench. On the other hand, the width W2 is an example of a second width, and the memory trench MT having the width W2 is an example of a second trench.

Similar to FIG. 6, FIG. 7 illustrates embedded insulating film 9 (insulating film 9a) formed in these memory trenches MT. Since the width W1 is narrow, the memory trenches MT having the width W1 are substantially filled with the insulating film 9a. On the other hand, since the width W2 is wide, the memory trench MT having the width W2 is not completely filled with the insulating film 9a. Thus, even after the insulating film 9a is formed, an opening T remains in the memory trench MT having the width W2. Similar to the memory trench MT itself, the opening T in the first embodiment is a trench extending in the Z direction and the Y direction.

The insulating film 9a according to the first embodiment is conformally formed within the memory trenches MT. Therefore, the insulating film 9a illustrated in FIG. 7 is formed on a +X direction side surface and a −X direction side surface of each memory trench MT having the width W2, and the opening T remains between the insulating films 9a on these side surfaces.

A thickness D of the insulating film 9a according to the first embodiment is at least ½ of the width W1 but less than ½ of the width W2 (W1/2≤D<W2/2). Accordingly, the insulating film 9a can be formed such that the memory trenches MT having the width W1 will be completely filled with the insulating film 9a and the memory trench MT having the width W2 will not be completely filled with the insulating film 9a. That is, the opening T can be formed in a self-aligning manner in any memory trench MT having the width W2. FIG. 7 further illustrates a width W (where W=W2−2×D) of the opening T. In other examples, the opening T may be formed by another method.

Similar to FIG. 6, FIG. 7 illustrates a seam S that may be formed in the insulating film 9a when the insulating film 9a fills the memory trench MT. The seam S illustrated in FIG. 7 is formed in the memory trench MT having the width W1. When the insulating film 9a is annealed, the seam S may cause a crack to form in the insulating film 9a. For example, when the insulating film 9a is annealed, stress may be generated in the insulating film 9a due to thermal shrinkage of the insulating film 9a, the stress may act on or at the seam S, and a crack may be generated from the seam S. As a result, the semiconductor device may become defective.

However, the insulating film 9a according to the first embodiment has the opening T in the memory trench MT having the width W2. Therefore, when the insulating film 9a is annealed, the stress can be dissipated, and the stress acting on the seam S can be reduced. Accordingly, likelihood of the generation of a crack from a seam S can be reduced.

It is desirable that the memory trench MT including the opening T is disposed close to the memory trench MT including a seam S. Accordingly, the stress acting on the seam S can be further reduced. For example, it is desirable to set a distance between the opening T and the seam S in a range of 1 μm to 10 μm. This can be executed, for example, by setting a pitch between the memory trenches MT having the width W2 to be relatively short when forming the plurality of memory trenches MT having the width W2. It is desirable to set the pitch to, for example, 50 μm or less.

The tunnel insulating film 6, the channel semiconductor layer 7, and the core insulating film 8 (see FIG. 3 and the like) according to the first embodiment are formed only in each memory trench MT having the width W1 and not in the memory trenches MT having the width W2. Therefore, each of the memory trenches MT illustrated in FIGS. 1, 2A and 2B, 3, 4A to 4C, and 5A to 5C has the width W1 even though memory trenches MT have the width W2 are formed at certain positions in the semiconductor device during manufacturing. When the semiconductor device according to the first embodiment is manufactured, if the number of memory trenches MT having the width W2 is kept too low, the stress cannot be sufficiently reduced, but if the number of memory trenches MT having the width W2 is made large, the number of memory cells in the semiconductor device is reduced. Therefore, it is desirable to adjust the number of memory trenches MT having the width W2 to an appropriate number that is neither too large nor too small. For example, the number of memory trenches MT having the width W2 may be adjusted to the appropriate number by setting the pitch between the memory trenches MT having the width W2 to be in a range of 3 μm to 50 μm.

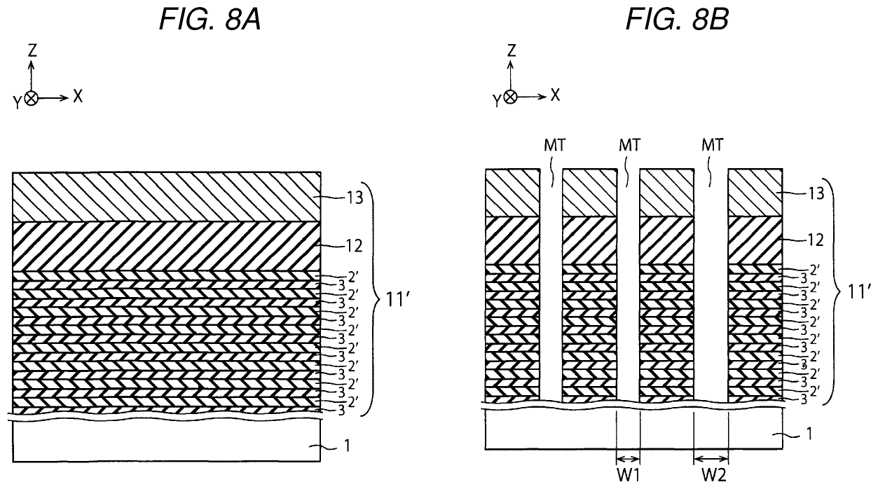

FIGS. 8A and 8B, 9A and 9B, 10A and 10B, and 11A and 11B are vertical cross-sectional views illustrating additional details of the method for manufacturing the semiconductor device according to the first embodiment. FIGS. 4A to 4C and FIGS. 5A to 5C illustrate transverse cross sections of the semiconductor device during manufacture, and FIGS. 8A and 8B, 9A and 9B, 10A and 10B, and 11A and 11B illustrate vertical cross sections of the semiconductor device during manufacture.

First, the multilayer film 11′ is formed on the substrate 1 (FIG. 8A). The multilayer film 11′ is formed so as to sequentially include the plurality of sacrificial layers 2′ and the plurality of insulating layers 3 alternately stacked on the substrate 1, the mask layer 12, and the mask layer 13.

Next, the plurality of memory trenches MT are formed in the multilayer film 11′ by lithography and RIE (FIG. 8B). These memory trenches MT are formed so as to include memory trenches MT having the width W1 and memory trenches MT having the width W2. FIG. 8B illustrates two memory trenches MT having the width W1 and one memory trench MT having the width W2. Each memory trench MT according to the first embodiment is formed so as to penetrate the multilayer film 11′. In a step illustrated in FIG. 8B, the plurality of recesses H1 are further formed on both side surfaces of each memory trench MT having the width W1 (see FIG. 4A).

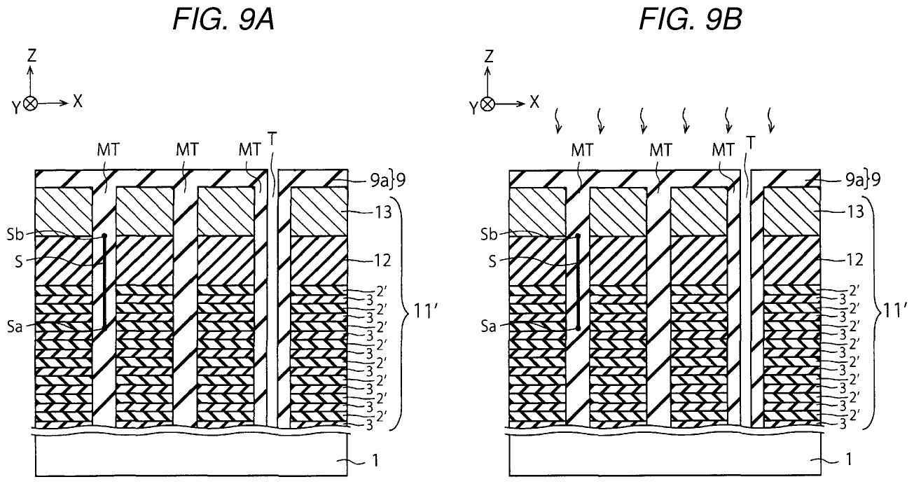

Next, the insulating film 9a for the embedded insulating film 9 is formed on the entire surface of the substrate 1 (FIG. 9A). As a result, the insulating film 9a is formed in each memory trench MT. In the first embodiment, each memory trench MT having the width W1 is completely filled with the insulating film 9a, but each memory trench MT having the width W2 is not completely filled with the insulating film 9a, so that the opening T remains in each memory trench MT having the width W2. In a step illustrated in FIG. 9A, when the insulating film 9a is formed in each memory trench MT, a seam S may be formed in any (or all) of the memory trenches MT having the width W1. The block insulating film 4 and the floating gates 5 are formed before the insulating film 9a is formed (see FIG. 4B).

Next, the insulating film 9a and the like are annealed (FIG. 9B). As a result, the insulating film 9a shrinks, and the stress is generated in the insulating film 9a. However, since the insulating film 9a has the opening T in a memory trench MT having the width W2, the stress acting on the seam S can be reduced, and the generation of the crack from the seam S can be reduced.

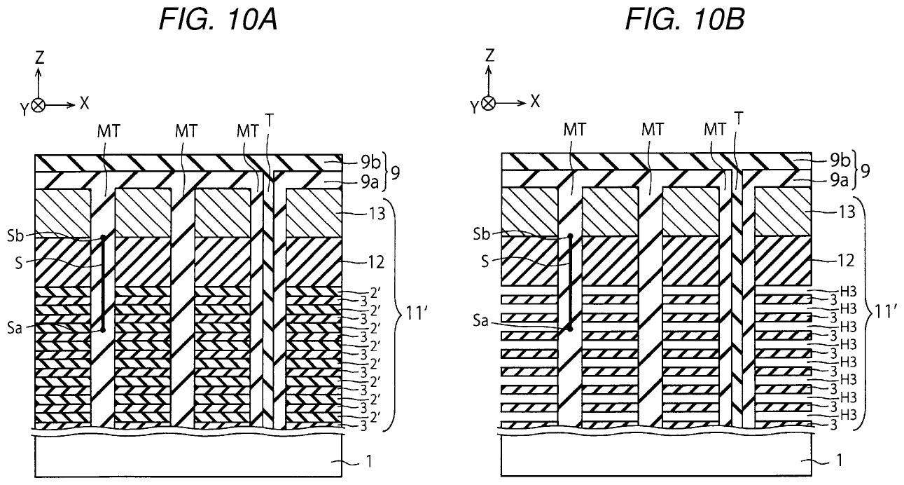

Next, an insulating film 9b for the embedded insulating film 9 is formed on the entire surface of the substrate 1 (FIG. 10A). As a result, the insulating film 9b enters the opening T, and the opening T is filled with the insulating film 9b. That is, each memory trench MT having the width W2 is now filled by the insulating films 9a and 9b. The insulating film 9b is, for example, a SiO₂ film. The insulating film 9b is an example of a second insulating material.

Next, a slit is formed in the multilayer film 11′ at a point not depicted, and each sacrificial layer 2′ is removed by wet etching via the slit (FIG. 10B). As a result, the plurality of cavities H3 are formed in the multilayer film 11′.

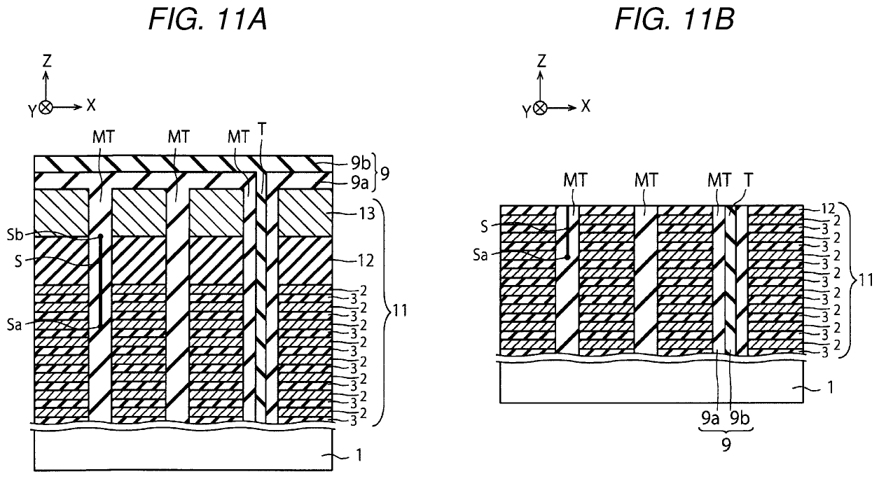

Next, the control gate 2 is formed in each cavity H3 (FIG. 11A). As a result, the multilayer film 11 alternately including control gates 2 and insulating layers 3 is formed on the substrate 1. That is, the plurality of sacrificial layers 2′ are replaced with the plurality of control gates 2. The multilayer film 11 illustrated in FIG. 11A further includes the mask layers 12 and 13.

Next, excess portions of mask layers 13 and 12 and insulating films 9a and 9b are removed by etching or chemical mechanical polishing (CMP) (FIG. 11B). In FIG. 11B, since an uppermost layer among the stack of control gates 2 and insulating layers 3 is a control gate 2, a part of the mask layer 12 is left. On the other hand, when the uppermost layer in the stack is an insulating layer 3, the mask layer 12 may be entirely removed. In this way, the semiconductor device according to the first embodiment is manufactured.

In FIG. 11B, the embedded insulating film 9 (the insulating film 9a) in the memory trench MT having the width W1 is an example of a first insulating film, and the embedded insulating film 9 (the insulating films 9a and 9b) in the memory trench MT having the width W2 is an example of a second insulating film.

The recess H2, the tunnel insulating film 6, the channel semiconductor layer 7, and the core insulating film 8 may be formed in any step after the insulating film 9a is formed (see FIG. 4C and FIG. 5A). The recess H2, the tunnel insulating film 6, the channel semiconductor layer 7, and the core insulating film 8 can be formed before the sacrificial layer 2′ is replaced with the control gate 2 in a method as illustrated in FIGS. 4A, 4B, and 4C and FIGS. 5A, 5B, and 5C, but may also be formed in other examples after the sacrificial layer 2′ is replaced with the control gate 2. The recess H2, the tunnel insulating film 6, the channel semiconductor layer 7, and the core insulating film 8 may be formed, for example, after the step illustrated in FIG. 11B in the method illustrated in FIGS. 8A and 8B, 9A and 9B, 10A and 10B, and FIGS. 11A and 11B. The recess H2, the tunnel insulating film 6, the channel semiconductor layer 7, and the core insulating film 8 according to the first embodiment are formed only in each memory trench MT having the width W1 and not in the memory trenches MT having the width W2.

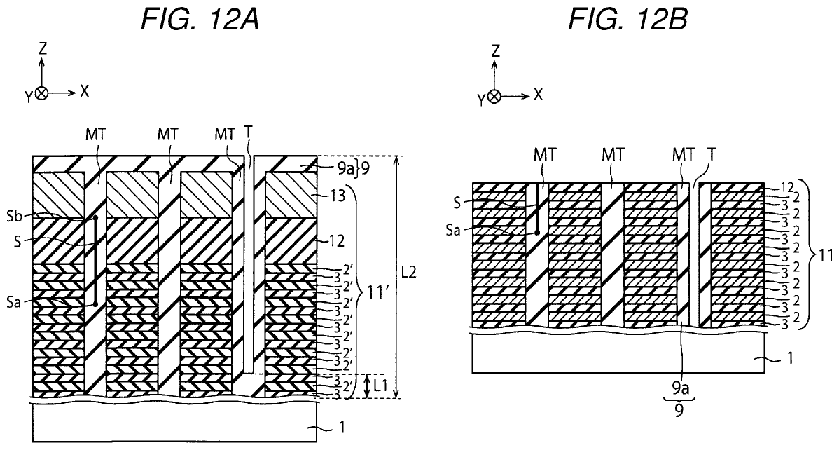

FIGS. 12A and 12B are vertical cross-sectional views illustrating a method for manufacturing a semiconductor device according to first and second modifications of the first embodiment.

FIG. 12A corresponds to a modification of the step illustrated in FIG. 9A. In FIG. 12A, the insulating film 9a is thickly formed at a bottom portion of the memory trench MT having the width W2. A reference sign L1 denotes a distance between a lower surface and an upper surface of the insulating film 9a at the bottom portion of the memory trench MT having the width W2. A reference sign L2 denotes a distance between a lower surface and an upper surface of the insulating film 9a for the entire insulating film 9a. Therefore, a value L2−L1 corresponds to a depth of the opening T. In order to sufficiently disperse the above stress, it is desirable that the depth L2−L1 of the opening T is set to at least ½ of the distance L2 (that, is, L2−L1≥L2/2). In FIG. 12A, the insulating film 9a may also be formed such that the opening T is closed in (pinched in) near or at an upper end of the opening T.

FIG. 12B corresponds to a modification of the step illustrated in FIG. 11B. In FIG. 12B, the excess mask layers 13 and 12 and insulating film 9a are removed before the insulating film 9b is formed. Thereafter, when an interlayer insulating film is formed on the multilayer film 11, the interlayer insulating film may be formed in a way that the opening T will not be filled with the interlayer insulating film. In this case, the opening T remains in a finished semiconductor device as an air gap left in the insulating film 9a.

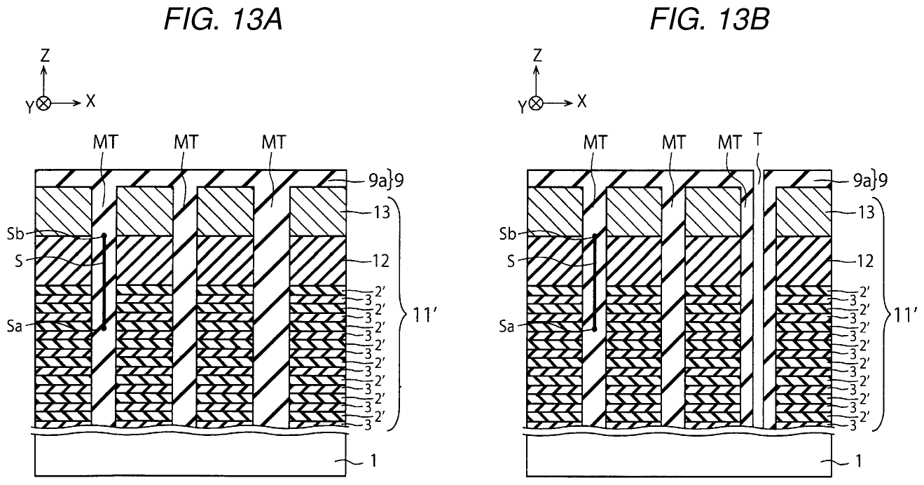

FIGS. 13A and 13B are vertical cross-sectional views illustrating a method for manufacturing a semiconductor device according to a third modification of the first embodiment.

FIG. 13A corresponds to a modification of the step illustrated in FIG. 9A. In FIG. 13A, not only the memory trench MT having the width W1 but also the memory trench MT having the width W2 is filled entirely with the insulating film 9a. In this case, before the insulating film 9a is annealed, the opening T is formed in the insulating film 9a in the memory trench MT having the width W2 by lithography and RIE (FIG. 13B). Accordingly, the above stress can be dispersed. Thus, the opening T may be formed in a self-aligning manner, as described above, when the insulating film 9a is formed, or may be formed by etching after the insulating film 9a is formed.

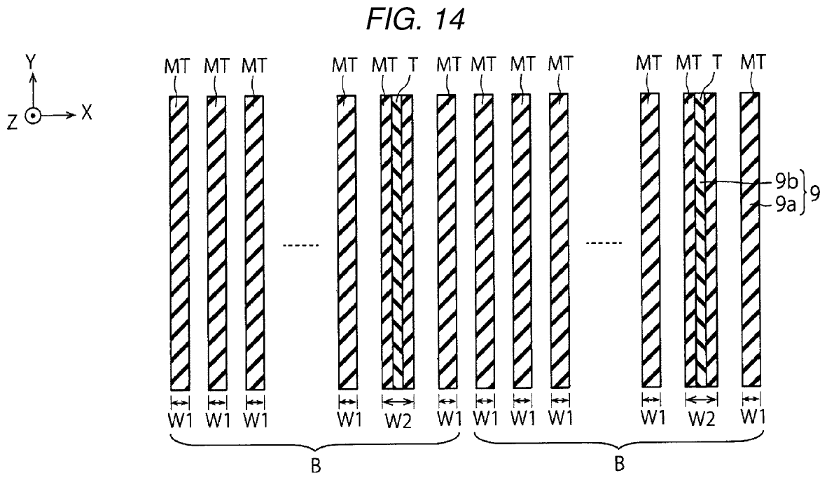

FIG. 14 is a transverse cross-sectional view schematically illustrating the structure of the semiconductor device according to the first embodiment.

Similar to FIG. 3, FIG. 14 illustrates cross sections of the plurality of memory trenches MT in the semiconductor device according to the first embodiment. In FIG. 14, illustrations of the block insulating film 4, the floating gate 5, the tunnel insulating film 6, the channel semiconductor layer 7, the core insulating film 8, and the like are omitted and just aspects of the memory trenches MT are depicted.

The semiconductor device according to the first embodiment may include a plurality of blocks B, which are constituent units of a three-dimensional memory device. FIG. 14 illustrates two of these blocks B. Each block B illustrated in FIG. 14 includes the plurality of memory trenches MT having the width W1 and one memory trench MT having the width W2. The semiconductor device according to the first embodiment may include one memory trench MT having the width W2 for each block B. Each block B includes, for example, thirty-one memory trenches MT having the width W1 and one memory trench MT having the width W2. Each memory trench MT having the width W1 includes the insulating film 9a, and each memory trench MT having the width W2 includes the insulating films 9a and 9b.

Each memory trench MT having the width W2 may be disposed at or near an outer edge of the block B or may be disposed at a position other than at or near an outer edge of in the block B. In other examples, more than one memory trench MT having the width W2 may be disposed in each block B, one memory trench MT having the width W2 may be disposed at a boundary between blocks B, or less than all blocks B may include a memory trench MT having the width W2. However, it is generally desirable that these memory trenches MT are disposed such that the pitch between the memory trenches MT having the width W2 is 50 μm or less. That is, it is desirable that an interval between a center line of one memory trench MT having the width W2 to a center line of the closest memory trench MT having the width W2 is set to 50 μm or less.

In the first embodiment, only a memory trench MT having the width W2 includes the opening T, and only the memory trenches MT having the width W1 include the channel semiconductor layer 7 and the like. However, in other examples, the semiconductor device according to the first embodiment may include a ladder-like structure that bridges between one side surface side and the other side surface side of each memory trench MT in each memory trench MT having the width W1 and each memory trench MT having the width W2.

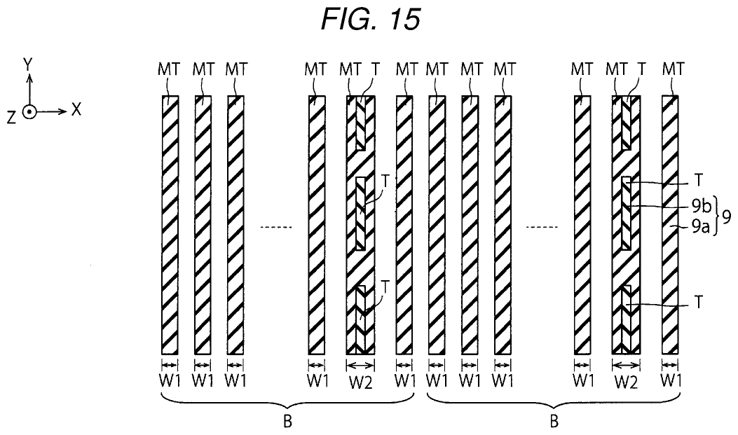

FIG. 15 is a transverse cross-sectional view schematically illustrating a structure of a semiconductor device according to a modification of the first embodiment.

Each opening T illustrated in FIG. 15 extends in the Z direction and the Y direction, similar to each opening T illustrated in FIG. 14. However, in FIG. 15, each memory trench MT having the width W2 includes a plurality of openings T arranged along the Y direction rather than just one continuous opening T. In other words, in each memory trench MT having the width W2 illustrated in FIG. 15, the insulating film 9a includes the plurality of openings T, and each opening T is filled with the insulating film 9b. However, as depicted, each memory trench MT having the width W2 may include a plurality of openings T or may include just one opening T.

The semiconductor device according to the first embodiment includes the memory trenches MT each having the width W1 and at least one memory trench MT having the width W2 larger than the width W1, and the insulating film 9a is formed or processed such that the openings T are formed in the memory trench MT having the width W2. Therefore, according to the first embodiment, the generation of cracks in the insulating film 9a when the insulating film 9a is annealed can be reduced.

### Second Embodiment

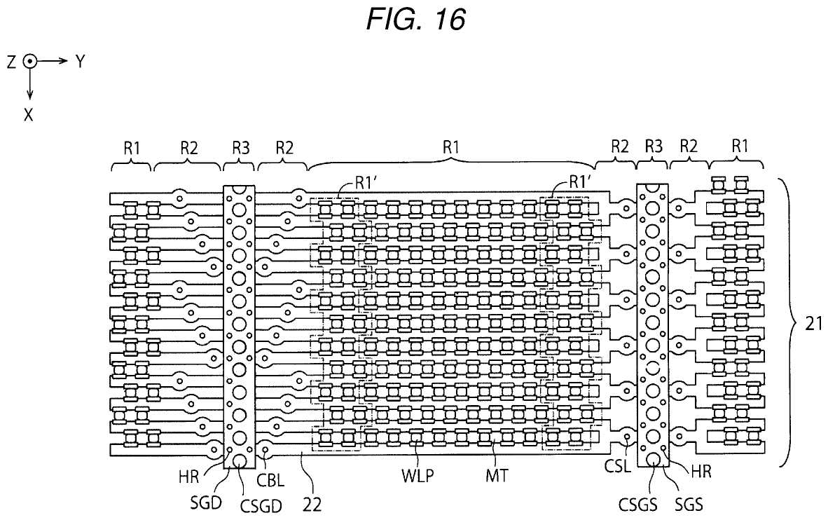

FIG. 16 is a plan view illustrating a structure of a semiconductor device according to a second embodiment. The semiconductor device according to the second embodiment is, for example, a three-dimensional memory device of a type different from that in the first embodiment, but has a structure similar at least in part to that of the three-dimensional memory device according to the first embodiment.

The semiconductor device according to the second embodiment includes a substrate 21, a plurality of channel semiconductor layers 22, a plurality of word line pillars WLP, and a plurality of memory trenches MT.

The substrate 21 is, for example, a semiconductor substrate such as a silicon substrate. FIG. 16 illustrates an X direction and a Y direction as being substantially parallel to a surface of the substrate 21 and perpendicular to each other, and a Z direction orthogonal to the surface of the substrate 21.

FIG. 16 illustrates regions R1, R2, and R3 on the substrate 21. The region R1 is a memory cell region in which memory cells are disposed. Each region R1 includes dummy cell regions R1′ in which dummy cells are disposed. The region R2 is a select gate region provided for select gates. Each region R1 is provided between a region R2 that is a source select gate region and a region R2 that is a drain select gate region. The region R3 is a staircase contact region in which contact plugs are disposed. Each region R3 for a source side includes a select gate SGS extending in the X direction, and a plurality of contact plugs CSGS and a plurality of dummy pillars HR provided on the select gate SGS. Each region R3 for a drain side includes a plurality of select gates SGD extending in the X direction and stacked in the Z direction, and a plurality of contact plugs CSGD and a plurality of dummy pillars HR provided on each select gate SGD.

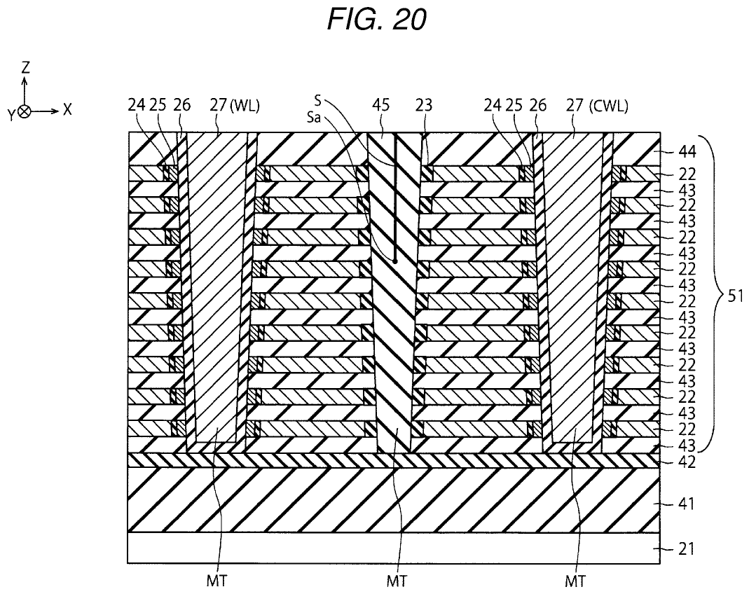

Each channel semiconductor layer 22 extends in the Y direction within the regions R1 and R2. In each region R1, the plurality of channel semiconductor layers 22 are adjacent to each other in the X direction. FIG. 16 further illustrates contact plugs CBL and CSL respectively provided for bit lines and source lines on these channel semiconductor layers 22. The semiconductor device according to the second embodiment includes a multilayer film 51 formed on the substrate 21 (see FIG. 20), and the multilayer film 51 includes the plurality of channel semiconductor layers 22 and a plurality of insulating layers 43 alternately stacked one on the other in the Z direction. The channel semiconductor layer 22 is an example of a semiconductor layer, and the multilayer film 51 is an example of a first film.

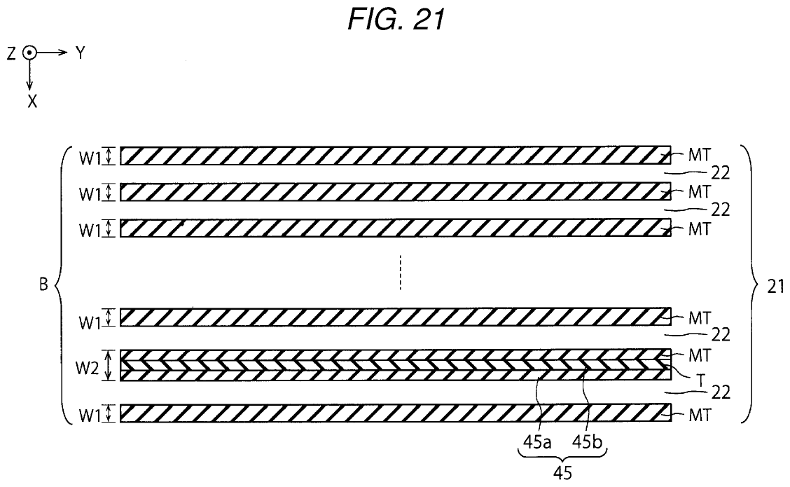

Each word line pillar WLP and each memory trench MT is disposed between a pair of channel semiconductor layers 22 adjacent to each other in the X direction. Each word line pillar WLP extends in the Z direction. Each memory trench MT extends in the Y direction and the Z direction. In each region R1, the plurality of channel semiconductor layers 22 and the plurality of memory trenches MT are alternately arranged with one another in the X direction. Each memory trench MT is filled with an embedded insulating film 45 (see FIG. 21).

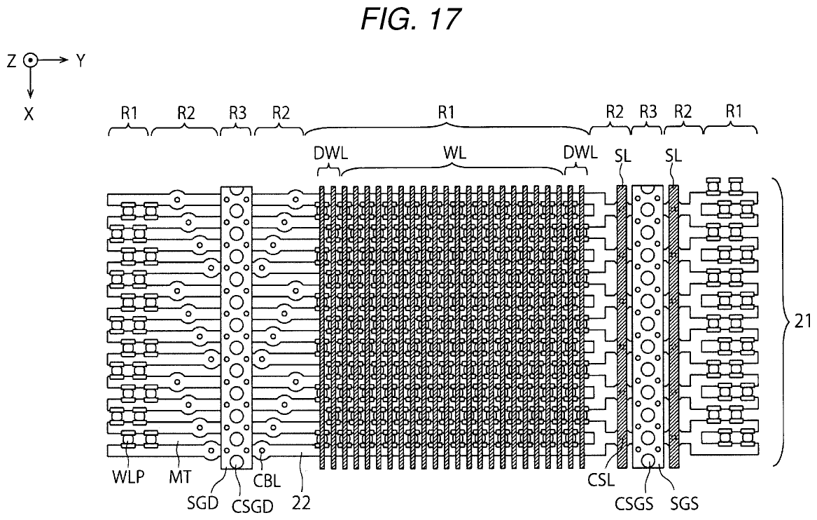

FIG. 17 is another plan view illustrating the structure of the semiconductor device according to the second embodiment.

FIG. 17 illustrates a plurality of word lines WL, a plurality of dummy word lines DWL, and a plurality of source lines SL provided on the substrate 21 in addition to the components already illustrated in FIG. 16. The word lines WL, the dummy word lines DWL, and the source lines SL all extend in the X direction.

Each word line WL is disposed on a plurality of corresponding word line pillars WLP in the region R1 excluding the region R1′. Each dummy word line DWL is disposed on a plurality of corresponding word line pillars WLP in the region R1′. Each source line SL is disposed on a plurality of corresponding contact plugs CSL in the region R2.

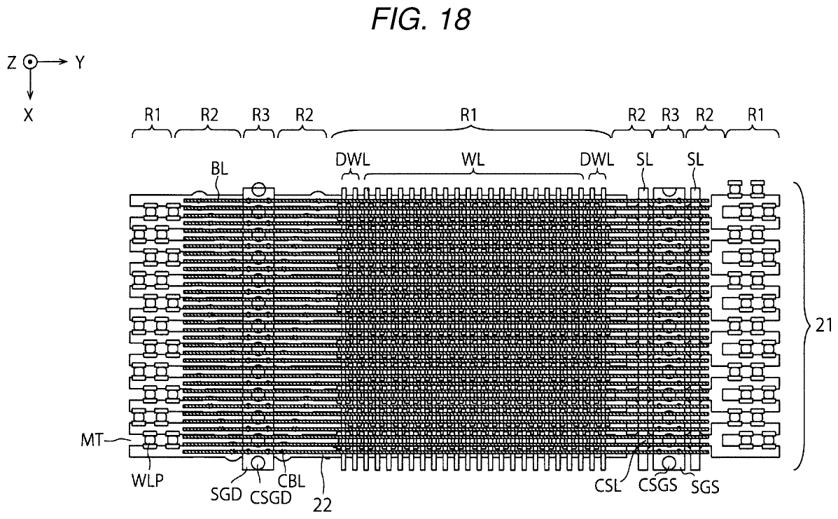

FIG. 18 is yet another plan view illustrating the structure of the semiconductor device according to the second embodiment.

FIG. 18 illustrates a plurality of bit lines BL provided on the substrate 21 in addition to the components already illustrated in FIG. 17. These bit lines BL extend in the Y direction. The bit line BL is disposed on the plurality of corresponding contact plugs CBL in the regions R1, R2, and R3.

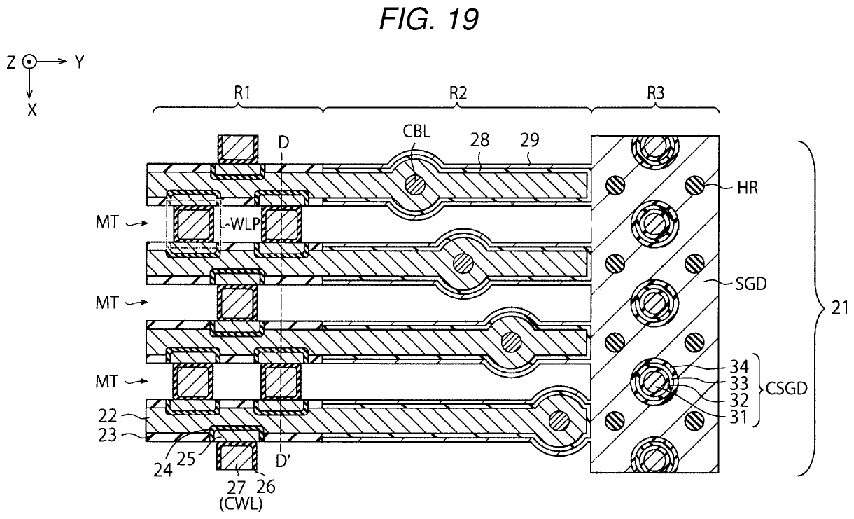

FIG. 19 is an enlarged plan view illustrating the structure of the semiconductor device according to the second embodiment. Specifically, FIG. 19 illustrates an enlarged view of one portion of region R1, one region R2, and one region R3 such as illustrated in FIG. 16.

In FIG. 19, each word line pillar WLP includes an electrode layer 27 (contact plug CWL) having a columnar shape extending in the Z direction, and a block insulating film 26 having a tubular shape extending in the Z direction. The block insulating film 26 surrounds the electrode layer 27 in a plan view.

In FIG. 19, each word line pillar WLP is sandwiched between a pair of charge accumulation layers 25 and a pair of tunnel insulating films 24 in the X direction. One charge accumulation layer 25 and one tunnel insulating film 24 are positioned together on a +X direction side surface of the block insulating film 26 in a, and are sandwiched between a block insulating film 26 and a channel semiconductor layer 22. Another charge accumulation layer 25 and tunnel insulating films 24 are positioned together on a −X direction side surface of the block insulating film 26, and are sandwiched between the block insulating film 26 and another channel semiconductor layer 22. Each charge accumulation layer 25 is, for example, a polysilicon layer, a metal layer, or a SiN film. Each charge accumulation layer 25 can accumulate signal charges of the three-dimensional memory for storing data or the like. The charge accumulation layer 25 is an example of a charge accumulation unit, and the pair of charge accumulation units 25 is an example of first and second charge accumulation units.

The semiconductor device illustrated in FIG. 19 further includes an insulating film 23, an insulating film 28, and a wiring layer 29 on both sides of each channel semiconductor layer 22. The wiring layer 29 is formed on the side surfaces of each channel semiconductor layer 22 via the insulating film 28, and is electrically connected to the select gate SGD. Each contact plug CSGD includes a wiring layer 31 extending in the Z direction and insulating films 32, 33, and 34 sequentially formed on a side surface of the wiring layer 31. The wiring layer 31 is electrically connected to one of the plurality of select gates SGD stacked in the Z direction.

Each memory trench MT is filled with an embedded insulating film 45 (see FIG. 21). Therefore, each word line pillar WLP illustrated in FIG. 19 is formed in the embedded insulating film 45.

FIG. 20 is a vertical cross-sectional view illustrating the structure of the semiconductor device according to the second embodiment. FIG. 20 illustrates a vertical cross section taken along a line D-D′ illustrated in FIG. 19. FIG. 20 illustrates an insulating film 41, an insulating film 42, the plurality of insulating layers 43, an insulating film 44, the embedded insulating film 45, the multilayer film 51, and a seam S in addition to the components already illustrated in FIG. 19.

The insulating film 41 is formed on the substrate 21. The insulating film 42 is formed on the insulating film 41. The multilayer film 51 is formed on the insulating film 42. The multilayer film 51 includes the insulating layers 43 and the channel semiconductor layers 22 alternately stacked on the insulating film 42, and the insulating film 44 on the stack of insulating layers 43 and channel semiconductor layers 22. Each of the insulating film 42, the insulating layers 43, and the insulating film 44 is, for example, a SiO₂ film.

FIG. 20 illustrates three memory trenches MT. These memory trenches MT penetrate the multilayer film 51. Each memory trench MT according to the second embodiment is filled with the embedded insulating film 45. However, since the vertical cross section illustrated in FIG. 20 illustrates a cross section at a position of two of the word line pillars WLP (see FIG. 19), two memory trenches MT are depicted as filled with the electrode layer 27 and the block insulating film 26 instead of the embedded insulating film 45. The memory trench MT between these two memory trenches MT illustrates the cross section at point filled by the embedded insulating film 35. Thus, FIG. 20 illustrates the electrode layer 27 and the block insulating film 26 formed in each memory trench MT, and a plurality of pairs of charge accumulation layers 25 and a plurality of pairs of tunnel insulating films 24 that sandwich the electrode layer 27 and the block insulating film 26.

FIG. 20 also illustrates a seam S formed in the embedded insulating film 45. The seam S can be formed when the embedded insulating film 45 fills the memory trench MT.

FIG. 21 is a cross-sectional view schematically illustrating the structure of the semiconductor device according to the second embodiment.

FIG. 21 illustrates a plurality of memory trenches MT in the semiconductor device according to the second embodiment. These memory trenches MT extend in the Z direction and the Y direction, and are arranged with respect to each other in the X direction. In FIG. 21, illustrations of the tunnel insulating film 24, the charge accumulation layer 25, the block insulating film 26, the electrode layer 27, and the like are omitted for simplicity.

The semiconductor device according to the second embodiment includes a plurality of blocks B. FIG. 21 illustrates one of these blocks B. The block B illustrated in FIG. 21 includes a plurality of memory trenches MT having the width W1 and one memory trench MT having the width W2. The semiconductor device according to the second embodiment includes one memory trench MT having the width W2 for each block B. Each memory trench MT having the width W1 includes an insulating film 45a, and each memory trench MT having the width W2 includes the insulating film 45a and an insulating film 45b. Each of the insulating film 45a and the insulating film 45b is, for example, a SiO₂ film. The embedded insulating film 45 (insulating film 45a) in the memory trench MT having the width W1 is an example of a first insulating film, and the embedded insulating film 45 (insulating films 45a and 45b) in the memory trench MT having the width W2 is an example of a second insulating film.

Each memory trench MT having the width W2 may be disposed at in an outer edge region of the block B or may be disposed at any position other than the outer edge region of the block B. In other examples, more than one memory trench MT having the width W2 may be disposed in each block B, or one memory trench MT having the width W2 may be disposed at boundary between blocks B or some blocks B may be without any memory trench MT having the width W2. However, it is generally desirable that the pitch between the memory trenches MT having the width W2 be 50 μm or less, as in the first embodiment. In this case, it is desirable to adjust the number of memory trenches MT having the width W2 to an appropriate number that is neither too large nor too small. For example, the pitch between the memory trenches MT having the width W2 may be in a range of 3 μm to 50 μm.

In the second embodiment, only the memory trenches MT having the width W2 is formed so as to include an opening T, and only memory trenches MT having the width W1 include the electrode layer 27 and the like. Further, similar to the first embodiment, a seam S according to the second embodiment may be formed in any or all of the memory trenches MT having the width W1. The semiconductor device according to the second embodiment may include a ladder-like structure that bridges between one side surface side and the other side surface side of each memory trench MT in each memory trench MT having the width W1 and each memory trench MT having the width W2.

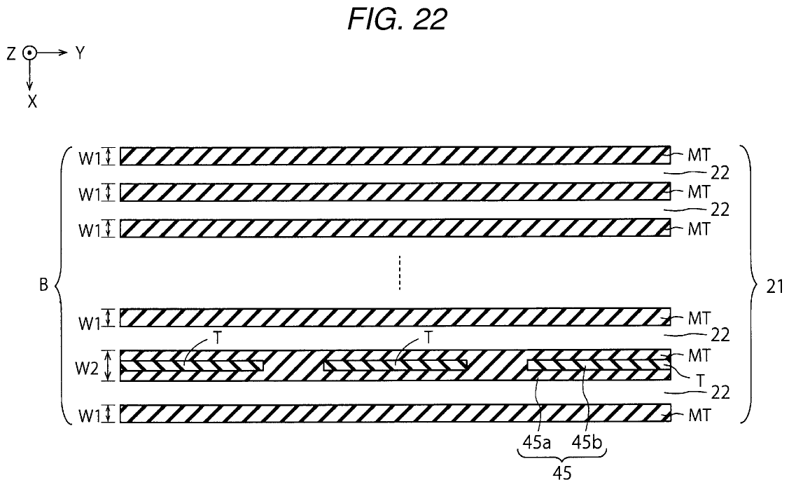

FIG. 22 is a cross-sectional view schematically illustrating a structure of a semiconductor device according to a modification of the second embodiment.

Each opening T illustrated in FIG. 22 extends in the Z direction and the Y direction, similar to each opening T illustrated in FIG. 21. However, in FIG. 22, each memory trench MT having the width W2 includes the plurality of openings T arranged along the Y direction. In other words, in each memory trench MT having the width W2 illustrated in FIG. 22, the insulating film 45a includes the plurality of openings T, and each opening T is filled with the insulating film 45b. Thus, each memory trench MT having the width W2 according to the second embodiment may include the plurality of openings T or may include one opening T.

The semiconductor device according to the second embodiment can be manufactured, for example, by the method illustrated in FIGS. 4A to 4C and FIGS. 5A to 5C or a method similar to the method illustrated in FIGS. 8A and 8B, 9A and 9B, 10A and 10B, and 11A and 11B. For example, the multilayer film 51 may be formed by alternately stacking a plurality of sacrificial layers and the plurality of insulating layers 43 and replacing these sacrificial layers with the plurality of channel semiconductor layers 22. These sacrificial layers are, for example, SiN films. However, since the multilayer film 51 includes a semiconductor layer (channel semiconductor layer 22) but not a metal layer, the multilayer film 51 may be formed without such a replacement technique. That is, the multilayer film 51 may be formed by alternately stacking the channel semiconductor layers 22 and the insulating layers 43. This also applies to the multilayer film 11 according to the first embodiment.

The memory trench MT according to the second embodiment can be formed in a multilayer film of sacrificial layers and of insulating layers 43 as in the step illustrated in FIG. 8B. In this case, the memory trenches MT according to the second embodiment are formed so as to include a memory trench MT having the width W1 and a memory trench MT having the width W2. Thereafter, the seam S and the opening T are formed by forming the insulating film 45a in these memory trenches MT. Accordingly, the generation of a crack from the seam S when the insulating film 45a is annealed can be reduced. Thereafter, the insulating film 45b is embedded in the opening T. The modifications illustrated in FIGS. 12A to 13B are also applicable to the second embodiment.

The semiconductor device according to the second embodiment includes memory trenches MT having the width W1 and a memory trench MT having the width W2 larger than the width W1, and the insulating film 45a is formed such that the opening T is formed in the memory trench MT having the width W2. Therefore, similar to the first embodiment, the generation of a crack in the insulating film 45a can be reduced.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a substrate;
a first film on the substrate and including a plurality of electrode layers and a plurality of insulating layers alternately stacked;
a plurality of insulating films in the first film, the insulating films extending in a first direction parallel to a surface of the substrate and spaced from each other in a second direction parallel to the surface of the substrate but intersecting the first direction;
a semiconductor layer in at least one of the plurality of insulating films;
a first charge accumulation unit between a first one of the electrode layers and the semiconductor layer in the second direction; and
a second charge accumulation unit between a second one of the electrode layers and the semiconductor layer in the second direction, the semiconductor layer being between the first and second charge accumulation units in the second direction, wherein
the plurality of insulating films include a first insulating film having a first width in the second direction and a second insulating film having a second width in the second direction, and
the second width is greater than the first width.

2. The semiconductor device according to claim 1, wherein the first insulating film includes a seam in an interior portion.

3. The semiconductor device according to claim 1, wherein the second insulating film includes an air gap in an interior portion.

4. The semiconductor device according to claim 1, wherein
the first insulating film is a first insulating material, and
the second insulating film comprises the first insulating material and a second insulating material.

5. The semiconductor device according to claim 4, wherein a thickness of the first insulating material in the second direction within the second insulating film is less than ½ of the second width.

6. The semiconductor device according to claim 1, wherein
the plurality of insulating films include a plurality of the second insulating films each having the second width, and
a pitch between the second insulating films is 50 μm or less.

7. The semiconductor device according to claim 1, wherein the semiconductor layer is in the first insulating film and has a tubular shape extending axially in a direction orthogonal to the surface of the substrate.

8. The semiconductor device according to claim 1, wherein the plurality of insulating films comprise silicon and oxygen.

9. A semiconductor device, comprising:
a substrate;
a first film on the substrate and including a plurality of semiconductor layers and a plurality of insulating layers alternately stacked;
a plurality of insulating films in the first film, the insulating films extending in a first direction parallel to a surface of the substrate, and spaced from each other in a second direction parallel to the surface of the substrate but intersecting the first direction;
an electrode layer in at least one of the plurality of insulating films;
a first charge accumulation unit between the electrode layer and a first one of the semiconductor layers in the second direction; and
a second charge accumulation unit between the electrode layer and a second one of the semiconductor layers in the second direction, the electrode layer being between the first and second charge accumulation units in the second direction, wherein
the plurality of insulating films include a first insulating film having a first width in the second direction and a second insulating film having a second width in the second direction, and
the second width is greater than the first width.

10. A method for manufacturing a semiconductor device, the method comprising:
forming a first film on a substrate, the first film including a plurality of first layers and a plurality of second layers alternately stacked;
forming a plurality of trenches in the first film; and
forming a first insulating material in the plurality of trenches, wherein
the first insulating material is formed in the plurality of trenches such that an opening is left in at least one of the plurality of trenches and at least another one of the plurality of trenches is filled with the first insulating material.

11. The method according to claim 10, wherein the plurality of trenches are formed so as to extend in a first direction parallel to a surface of the substrate and spaced from each other a second direction parallel to the surface of the substrate but intersecting the first direction.

12. The method according to claim 11, wherein the opening extends continuously in the first direction.

13. The method according to claim 11, wherein
the first insulating material is formed such that a plurality of the openings are formed in the at least one of the plurality of trenches, and
the plurality of openings are spaced from one another along the first direction.

14. The method according to claim 11, wherein
the plurality of trenches include a first trench having a first width in the second direction and a second trench having a second width in the second direction that is greater than the first width, and
the opening is in the second trench.

15. The method according to claim 14, wherein a seam is formed in the first insulating material in the first trench.

16. The method according to claim 14, wherein a thickness of the first insulating material in the second direction from a sidewall of the second trench is less than ½ of the second width.

17. The method according to claim 14, wherein
the plurality of trenches include a plurality of the second trenches having the second width, and
a pitch between the second trenches is 50 μm or less.

18. The method according to claim 10, further comprising:
annealing the first insulating material.

19. The method according to claim 18, wherein the first insulating material shrinks in the annealing.

20. The method according to claim 18, further comprising:
forming a second insulating material on the first insulating material after annealing the first insulating material, wherein
at least a part of the second insulating material is in the opening.
